(19) United States
(12) Patent Application Publication
(10) Pub. No.: US 2020/0127044 A1
(43) Pub. Date: Apr. 23, 2020

(54) METHOD FOR PRODUCING SEMICONDUCTOR EPITAXIAL WAFER, SEMICONDUCTOR EPITAXIAL WAFER, AND METHOD OF PRODUCING SOLID-STATE IMAGE SENSING DEVICE

(71) Applicant: SUMCO Corporation, Tokyo (JP)

(72) Inventors: Takeshi Kadono, Minato-ku (JP); Kazunari Kurita, Minato-ku (JP)

(73) Assignee: SUMCO Corporation, Tokyo (JP)

(21) Appl. No.: 16/717,763

(22) Filed: Dec. 17, 2019

Related U.S. Application Data
(63) Continuation of application No. 14/442,367, filed on May 12, 2015.

(30) Foreign Application Priority Data
Nov. 13, 2012 (JP) 2012 249598

(51) Int. Cl. H01L 27/146; H01L 21/322; H01L 21/265; H01L 21/02; C23C 16/24; C23C 16/02; C30B 25/20

(52) U.S. Cl. CPC H01L 27/14687; H01L 21/02439; H01L 21/26566; H01L 21/26506; H01L 21/02658; H01L 21/02381; H01L 21/2658; C23C 16/24; C23C 16/0263; C23C 16/0209; C30B 25/20; H01L 27/14683; H01L 21/26513; H01L 27/14689; H01L 21/02532; H01L 21/02576; H01L 21/02579; H01L 21/3221

(57) ABSTRACT

An object is to provide a method of producing a semiconductor epitaxial wafer having higher gettering capability and a reduced haze level of the surface of a semiconductor epitaxial layer.

The method of producing a semiconductor epitaxial wafer, according to the present invention includes: a first step of irradiating a semiconductor wafer 10 with cluster ions 16 thereby forming a modifying layer 18 formed from a constituent element of the cluster ions 16 contained as a solid solution, in a surface portion 10A of the semiconductor wafer; a second step of performing heat treatment for crystallinity recovery on the semiconductor wafer 10 after the first step such that the haze level of the semiconductor wafer surface portion 10A is 0.20 ppm or less; and a third step of forming an epitaxial layer 20 on the modifying layer 18 of the semiconductor wafer after the second step.

### TECHNICAL FIELD

The present invention relates to a method of producing a semiconductor epitaxial wafer, a semiconductor epitaxial wafer, and a method of producing a solid-state image sensing device. The present invention relates, in particular, to a method of producing a semiconductor epitaxial wafer, which wafer can suppress metal contamination by achieving higher gettering capability and the haze level of a surface portion of an epitaxial layer of which is reduced.

### BACKGROUND

Metal contamination is one of the factors that deteriorate the characteristics of a semiconductor device. For example, for a back-illuminated solid-state image sensing device, metal mixed into a semiconductor epitaxial wafer to be a substrate of the device causes increased dark current in the solid-state image sensing device, and results in the formation of defects referred to as white spot defects. In recent years, back-illuminated solid-state image sensing devices have been widely used in digital video cameras and mobile phones such as smartphones, since they can directly receive light from the outside, and take sharper images or motion pictures even in dark places and the like due to the fact that a wiring layer and the like thereof are disposed at a lower layer than a sensor section. Therefore, it is desirable to reduce white spot defects as much as possible.

Mixing of metal into a wafer mainly occurs in a process of producing a semiconductor epitaxial wafer and a process of producing a solid-state image sensing device (device fabrication process). Metal contamination in the former process of producing a semiconductor epitaxial wafer may be due to heavy metal particles from components of an epitaxial growth furnace, or heavy metal particles caused by the metal corrosion of piping materials of the furnace due to chlorine-based gas used during epitaxial growth in the furnace. In recent years, such metal contaminations have been reduced to some extent by replacing components of epitaxial growth furnaces with highly corrosion resistant materials, but not to a sufficient extent. On the other hand, in the latter process of producing a solid-state image sensing device, heavy metal contamination of semiconductor substrates would occur in process steps such as ion implantation, diffusion, and oxidizing heat treatment in the producing process.

For those reasons, conventionally, heavy metal contamination of semiconductor epitaxial wafers has been prevented by forming, in the semiconductor wafer, a gettering sink for trapping the metal, or by using a substrate having high ability to trap the metal (gettering capability), such as a high boron concentration substrate.

In general, a gettering sink is formed in a semiconductor wafer by an intrinsic gettering (IG) method in which an oxygen precipitate (commonly called a silicon oxide precipitate, and also called a bulk micro defect (BMD)) or dislocation that are crystal defects is formed within the semiconductor wafer, or an extrinsic gettering (EG) method in which the gettering sink is formed on the rear surface of the semiconductor wafer.

Here, a technique of forming a gettering site in a semiconductor wafer by monomer ion (single ion) implantation can be given as a technique for gettering heavy metal. JP H06-338507 A (PTL 1) discloses a production method, by which carbon ions are implanted through a surface of a silicon wafer to form a carbon ion implanted region, and an epitaxial silicon layer is formed on the surface thereby obtaining an epitaxial silicon wafer. In that technique, the carbon ion implanted region serves as a gettering site.

Further, J P 2008-294245 A (PTL 2) describes a technique of forming a carbon implanted layer by implanting carbon ions into a silicon wafer; then performing heat treatment for crystallinity recovery which has been degraded by the ion implantation (hereinafter referred to as “recovery heat treatment”) on the wafer, using an RTA (Rapid Thermal Annealing) apparatus, thereby shortening the recovery heat treatment process; and then forming a silicon epitaxial layer.

Furthermore, JP 2010-177233 (PTL 3) describes a method of producing an epitaxial wafer, in which a silicon single crystal substrate is ion-implanted with at least one of boron, carbon, aluminum, arsenic, and antimony at a dose in the range of 5×10¹⁴ atoms/cm² to 1×10¹⁶ atoms/cm², and after cleaning performed without performing recovery heat treatment on the silicon single crystal substrate, an epitaxial layer is formed at a temperature of 1100° C. or more using a single-wafer processing epitaxial apparatus.

### CITATION LIST

### Patent Literature

PTL 1: JP H06-338507 A

PTL 2: JP 2008-294245 A

PTL 3: JP 2010-177233 A

### SUMMARY

In all of the techniques described in PTLs 1 to 3, monomer ions are implanted into a semiconductor wafer before the formation of an epitaxial layer. However, according to studies made by the inventors of the present invention, it was found that the gettering capability is insufficient in semiconductor epitaxial wafers subjected to monomer-ion implantation, and stronger gettering capability is desired.

Further, in order to obtain a high quality semiconductor device from a semiconductor epitaxial wafer, it is important that the flatness of the surface of an epitaxial layer is high (the haze level is low).

In view of the above problems, an object of the present invention is to provide a semiconductor epitaxial wafer having higher gettering capability and a reduced haze level of the surface of a semiconductor epitaxial layer, a method of producing the semiconductor epitaxial wafer, and a method of producing a solid-state image sensing device by which a solid-state image sensing device is formed from the semiconductor epitaxial wafer.

According to studies made by the inventors of the present invention, it was found that irradiating a semiconductor wafer with cluster ions is advantageous in the following points as compared with the case of implanting monomer ions. Specifically, even if irradiation with cluster ions is performed at an acceleration voltage equivalent to the case of monomer ion implantation, the energy per one atom or one molecule applied to the irradiated semiconductor wafer is lower than in the case of monomer ion implantation. This results in higher peak concentration in the depth direction profile of the irradiation element, and allows the peak position to approach the surface of the semiconductor wafer. Thus, the gettering capability was found to be improved. Further, since irradiation is performed with an aggregate of a plurality of atoms or molecules in the cluster ion irradiation, the crystallinity of the outermost surface of the semiconductor wafer may be degraded depending on the size or the dose of the cluster ions used, which would deteriorate the flatness (increase the haze level) of the epitaxial layer surface. Correspondingly, it was found when recovery heat treatment is performed after the cluster ion irradiation to recover the haze level of the surface portion of the semiconductor wafer to a certain level, and an epitaxial layer is then formed; the haze level of the epitaxial layer surface portion can be sufficiently reduced.

Based on the above findings, the inventors completed the present invention.

Specifically, a method of producing a semiconductor epitaxial wafer, according to the present invention comprises: a first step of irradiating a semiconductor wafer with cluster ions thereby forming a modifying layer formed from a constituent element of the cluster ions contained as a solid solution, in a surface portion of the semiconductor wafer; a second step of performing heat treatment for crystallinity recovery on the semiconductor wafer after the first step such that the haze level of the surface portion of the semiconductor wafer is 0.20 ppm or less; and a third step of forming an epitaxial layer on the modifying layer of the semiconductor wafer after the second step.

Here, the semiconductor wafer may be a silicon wafer.

Further, the semiconductor wafer may be an epitaxial silicon wafer in which an epitaxial silicon layer is formed on a surface of a silicon wafer. In this case, the modifying layer is formed in the surface portion of the epitaxial silicon layer in the first step.

Here, the cluster ions preferably contain carbon as a constituent element. More preferably, the cluster ions contain at least two kinds of elements including carbon as constituent elements.

Here, the dose of the cluster ions of carbon is preferably 2.0×10¹⁴ atoms/cm² or more.

Next, a semiconductor epitaxial wafer according to the present invention comprises: a semiconductor wafer; a modifying layer formed from a certain element contained as a solid solution in the semiconductor wafer, the modifying layer being formed in a surface portion of the semiconductor wafer; and an epitaxial layer on the modifying layer. The half width of the concentration profile of the certain element in the depth direction of the modifying layer is 100 nm or less, and the haze level of the surface portion of the epitaxial layer is 0.30 ppm or less.

Here, the semiconductor wafer may be a silicon wafer.

Further, the semiconductor wafer may be an epitaxial silicon wafer in which an epitaxial silicon layer is formed on a surface of a silicon wafer. In this case, the modifying layer is placed in the surface portion of the epitaxial silicon layer.

Moreover, the peak of the concentration profile in the modifying layer preferably lies at a depth within 150 nm from the surface of the semiconductor wafer. The peak concentration of the concentration profile in the modifying layer is preferably 1×10¹⁵ atoms/cm³ or more.

Here, the certain element preferably includes carbon. More preferably, the certain element includes at least two kinds of elements including carbon.

In a method of producing a solid-state image sensing device according to the present invention, a solid-state image sensing device is formed on the epitaxial layer placed on the surface of the epitaxial wafer fabricated by any one of the above production methods or of any one of the above epitaxial wafers.

### Advantageous Effect of Invention

According to the present invention, a semiconductor wafer is irradiated with cluster ions to form a modifying layer formed from a constituent clement of the cluster ions contained as a solid solution, in a surface portion of the semiconductor wafer, and then heat treatment for recovering the haze level of the semiconductor wafer surface portion is performed on the semiconductor wafer, which resulted in a semiconductor epitaxial wafer, which wafer can suppress metal contamination by achieving higher gettering capability and the haze level of the surface portion of an epitaxial layer of which is reduced; and a high quality solid-state image sensing device can be formed from the semiconductor epitaxial wafer.

### BRIEF DESCRIPTION OF THE DRAWINGS

FIGS. 1(A) to 1(D) are schematic cross-sectional views illustrating a method of producing a semiconductor epitaxial wafer 100 according to a first embodiment of the present invention.

FIGS. 2(A) to 2(E) are schematic cross-sectional views illustrating a method of producing a semiconductor epitaxial wafer 200 according to another embodiment of the present invention.

FIG. 3(A) is a schematic view illustrating the irradiation mechanism for irradiation with cluster ions. FIG. 3(B) is a schematic view illustrating the implantation mechanism for implanting a monomer ion.

FIG. 4 shows the concentration profile of carbon, obtained by SIMS analysis in Reference Examples 1 and 2.

FIG. 5(A) and FIG. 5(B) are graphs showing the carbon concentration profile of a epitaxial silicon wafer with the Ni concentration profile after the gettering capability evaluation in Example 1 and Comparative Example 4, respectively.

### DETAILED DESCRIPTION

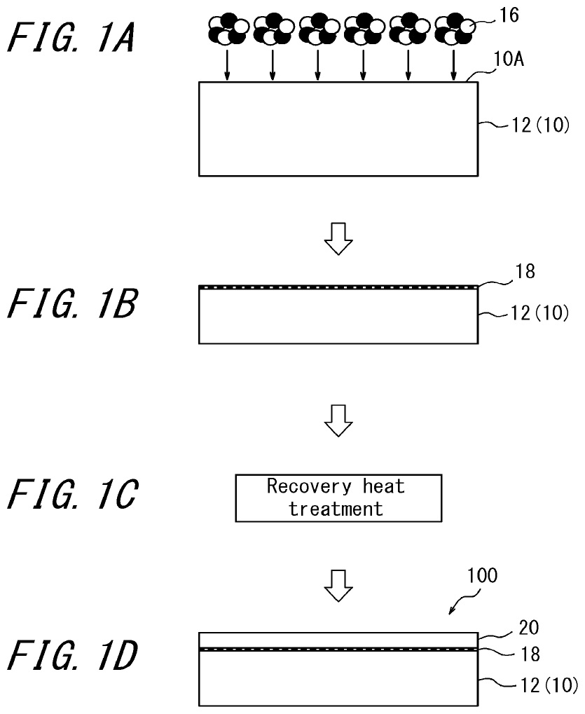

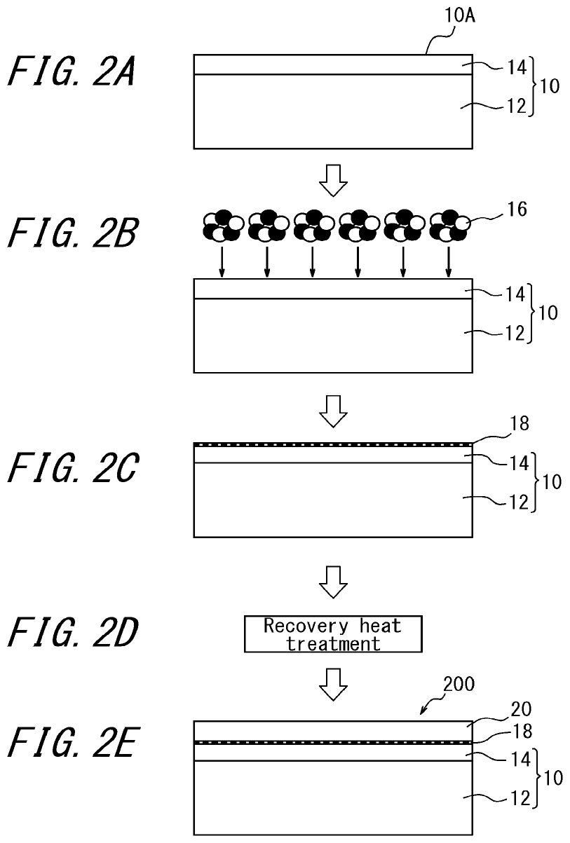

Embodiments of the present invention will now be described in detail with reference to the drawings. In principle, the same components are denoted by the same reference numeral, and the description will not be repeated. Further, in FIGS. 1(A) to 1(D) and FIGS. 2(A) to 2(E), a first epitaxial layer 14 and a second epitaxial layer 20 are exaggerated with respect to a semiconductor wafer 10 in thickness for the sake of explanation, so the thickness ratio does not conform to the actual ratio.

### (Method of Producing Semiconductor Epitaxial Wafer)

A method of producing a semiconductor epitaxial wafer 100 according to a first embodiment of the present invention includes, as shown in EEGs, 1(A) to 1(D), a first step (FIGS. 1(A) and 1(B)) of irradiating a semiconductor wafer 10 with cluster ions 16 to form a modifying layer 18 formed from a constituent element of the cluster ions 16 in a surface portion 10A of the semiconductor wafer 10; a second step (FIG. 1(C)) of performing heat treatment for crystallinity recovery (recovery heat treatment) on the semiconductor wafer 10 such that the haze level of the surface portion 10A of the semiconductor wafer 10 is 0.20 ppm or less; and a third step (FIG. 1(D)) of forming an epitaxial layer 20 on the modifying layer 18 of the semiconductor wafer 10. FIG. 1(D) is a schematic cross-sectional view of the semiconductor epitaxial wafer 100 obtained by this production method.

Examples of the semiconductor wafer 10 include, for example, a bulk single crystal wafer including silicon or a compound semiconductor (GaAs, GaN, or SiC) with no epitaxial layer on the surface thereof. In the case of producing a back-illuminated solid-state image sensing device, a bulk single crystal silicon wafer is typically used. Further, the semiconductor wafer 10 may be prepared by growing a single crystal silicon ingot by the Czochralski process (CZ process) or floating zone melting process (FZ process) and slicing it with a wire saw or the like. Further, carbon and/or nitrogen may be added thereto to achieve higher gettering capability. Furthermore, the semiconductor wafer 10 may be made n-type or p-type by adding a given impurity dopant. The first embodiment shown in FIGS. 1(A) to 1(D) is an example of using a bulk semiconductor wafer 12 with no epitaxial layer on its surface, as the semiconductor wafer 10.

Alternatively, an epitaxial semiconductor wafer in which a semiconductor epitaxial layer (first epitaxial layer) 14 is formed on a surface of the bulk semiconductor wafer 12 as shown in FIG. 2(A), can be given as an example of the semiconductor wafer 10. An example is an epitaxial silicon wafer in which a silicon epitaxial layer is formed on a surface of a bulk single crystal silicon wafer. The silicon epitaxial layer can be formed by chemical vapor deposition (CVD) process under typical conditions. The first epitaxial layer 14 preferably has a thickness in the range of 0.1 μm to 10 μm, more preferably in the range of 0.2 μm to 5 μm.

A method of producing a semiconductor epitaxial wafer 200 according to a second embodiment of the present invention includes, as shown in FIGS. 2(A) to 2(E), a first step (FIGS. 2(A) to 2(C)) of irradiating a semiconductor wafer 10, in which a first epitaxial layer 14 is formed on a surface (at least one side) of the bulk semiconductor wafer 12, with cluster ions 16 to form a modifying layer 18 formed horn a constituent element of the cluster ions 16 in a surface portion 10A of the semiconductor wafer (the surface portion of the first epitaxial layer 14 in this embodiment); a second step (FIG. 2(D)) of performing heat treatment for crystallinity recovery (recovery heat treatment) on the semiconductor wafer 10 such that the haze level of the surface portion 10A of the semiconductor wafer is 0.20 ppm or less; and a third step (FIG. 2(E)) of forming an epitaxial layer 20 on the modifying layer 18 of the semiconductor wafer 10. FIG. 2(E) is a schematic cross-sectional view of the semiconductor epitaxial wafer 200 obtained by this production method.

Here, the step of irradiation with cluster ions shown in FIG. 1(A) and FIG. 2(B) is one of the characteristic steps of the present invention. The technical meaning of employing the characteristic step will be described with the operation and effect. The modifying layer 18 formed as a result of irradiation with the cluster ions 16 is a region where the constituent element of the cluster ions 16 is localized as a solid solution at crystal interstitial positions or substitution positions in the crystal lattice of the surface portion of the semiconductor wafer, which region functions as a gettering site. The reason may be as follows. After irradiation in the form of cluster ions, elements such as carbon and boron are localized at high density at substitution positions and interstitial positions in the silicon single crystal. It has been experimentally found that when carbon or boron are turned into solid solutions to the equilibrium concentration of the silicon single crystal or higher, the solid solubility of heavy metals (saturation solubility of transition metal) extremely increases. In other words, it appears that carbon and boron made into a solid solution to the equilibrium concentration or higher increases the solubility of heavy metals, which results in significantly increased rate of trapping the heavy metals.

Here, since irradiation is performed with the cluster ions 16 in the present invention, higher gettering capability can be achieved as compared with the case of implanting monomer ions. Therefore, the semiconductor epitaxial wafers 100 and 200 achieving higher gettering capability can be produced, and the formation of white spot defects is expected to be suppressed in back-illuminated solid-state image sensing devices produced from the semiconductor epitaxial wafers 100 and 200 obtained by the production methods as compared to the conventional devices.

Note that “cluster ions” herein mean clusters formed by aggregation of a plurality of atoms or molecules, which have been ionized by being positively or negatively charged. A cluster is a bulk aggregate having a plurality (typically 2 to 2000) of atoms or molecules bound together.

The inventors of the present invention consider that the mechanism of achieving high gettering capability by the irradiation with the cluster ions is as follows.

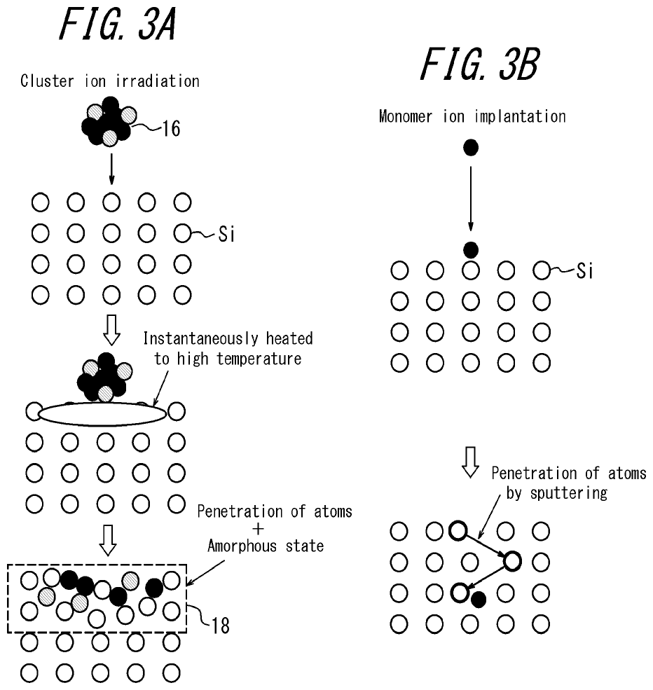

For example, when carbon monomer ions are implanted into a silicon wafer, the monomer ions sputter silicon atoms forming the silicon wafer to be implanted to a predetermined depth position in the silicon wafer, as shown in FIG. 3(B). The implantation depth depends on the kind of the constituent element of the implantation ions and the acceleration voltage of the ions. In this case, the concentration profile of carbon in the depth direction of the silicon wafer is relatively broad, and the carbon implanted region extends approximately 0.5 μm to 1 μm. When the implantation is performed simultaneously with a plurality of species of ions at the same energy, lighter elements are implanted more deeply, in other words, elements are implanted at different positions depending on their mass. Accordingly, the concentration profile of the implanted elements is broader in such a case.

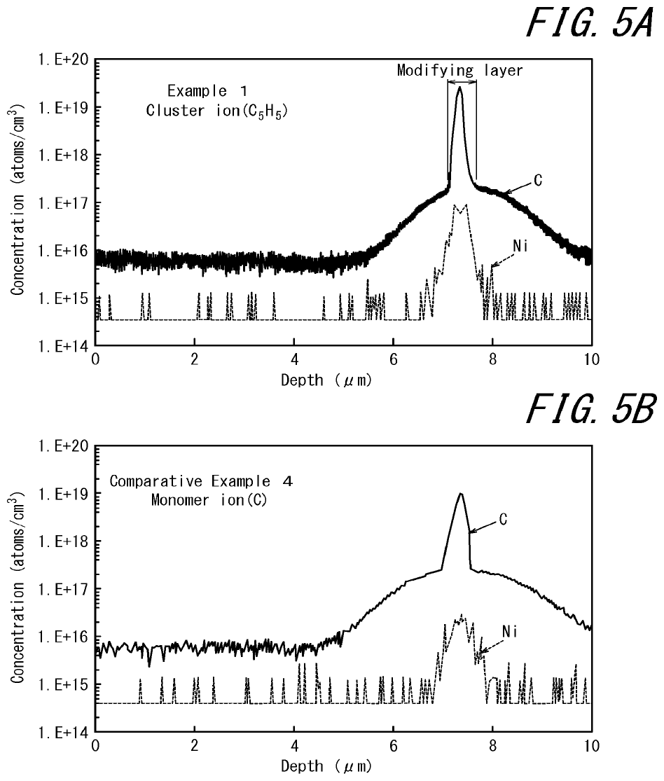

On the other hand, in cases where the silicon wafer is irradiated with cluster ions, for example, composed of carbon and boron, as shown in FIG. 3(A), when the silicon wafer is irradiated with the cluster ions 16, the ions are instantaneously rendered to a high temperature state of about 1350° C. to 1400° C. due to the irradiation energy, thus melting silicon. After that, the silicon is rapidly cooled to form a solid solution of carbon and boron in the vicinity of the surface of the silicon wafer. Correspondingly, a “modifying layer” herein means a layer in which the constituent elements of the ions used for irradiation form a solid solution at crystal interstitial positions or substitution positions in the crystal lattice of the surface portion of the semiconductor wafer. The concentration profile of carbon and boron in the depth direction of the silicon wafer is sharper as compared with the case of monomer ions, although depending on the acceleration voltage and the cluster size of the cluster ions. The region where carbon and boron are localized (that is, the modifying layer) is a region having a thickness of approximately 500 nm or less (for example, about 50 nm to 400 nm). Note that the elements used for the irradiation in the form of cluster ions are thermally diffused to some extent in the course of formation of the epitaxial layer 20. Accordingly, in the concentration profile of carbon and boron after the formation of the epitaxial layer 20, broad diffusion regions are formed on both sides of the peaks indicating the localization of these elements. However, the thickness of the modifying layer does not change significantly (see FIG. 5(A) described below). Consequently, carbon and boron are precipitated at a high concentration in a localized region. Since the modifying layer 18 is formed in the vicinity of the surface of the silicon wafer, further proximity gettering can be performed. This is considered to result in achievement of higher gettering capability than in the case of implanting monomer ions. Note that the irradiation can be performed simultaneously with a plurality of species of ions in the form of cluster ions in a single cluster ion irradiation step, which is also advantageous.

Monomer ions are typically implanted at an acceleration voltage of about 150 keV to 2000 keV. However, since the ions collide with silicon atoms with the energy, which results in significantly degraded crystallinity of the surface portion of the silicon wafer, which has been implanted with the monomer ions. Accordingly, even if heat treatment for recovering the crystallinity degraded after the ion implantation (recovery heat treatment), the haze level of the surface portion of the semiconductor wafer to be formed later is recovered at a low rate.

In general, irradiation with cluster ions is performed at an acceleration voltage of about 10 keV/Cluster to 100 keV/Cluster. However, since a cluster is an aggregate of a plurality of atoms or molecules, the ions can be implanted at reduced energy per one atom or one molecule. This results in less damage to the crystal of the surface portion of the semiconductor wafer. Further, cluster ion irradiation does not degrade the crystallinity of a surface portion of a semiconductor wafer as compared with monomer-ion implantation also due to the implantation mechanism shown in FIG. 3, However, the crystallinity of the outermost surface of the semiconductor wafer may be degraded depending on the size or the dose of the cluster ions used, which would increase the haze level of the epitaxial layer surface, Even in that case, the haze level of the surface portion of the epitaxial layer 20 can be sufficiently reduced by performing recovery heat treatment under certain conditions in the second step after the first step and then performing the third step of epitaxially growing the epitaxial layer 20.

The cluster ions 16 may include a variety of clusters depending on the binding mode, and can be generated, for example, by known methods described in the following documents. Methods of generating gas cluster beam are described in (1) JP 09-041138 A and (2) JP 04-354865 A. Methods of generating ion beam are described in (1) Junzo Ishikawa, “Charged particle beam engineering”, ISBN 978-4-339-00734-3 CORONA PUBLISHING, (2) The Institution of Electrical Engineers of Japan, “Electron/Ion Beam Engineering”, Ohmsha, ISBN 4-88686-217-9, and (3) “Cluster ion Beam-Basic and Applications”, THE. NIKKAN KOGYO SHIMBUN, ISBN 4-526-05765-7. In general, a Nielsen ion source or a Kaufman ion source is used for generating positively charged cluster ions, whereas a high current negative ion source using volume production is used for generating negatively charged cluster ions.

The conditions for irradiation with cluster ions will be described below. First, examples of the element used for irradiation include, but not limited to, carbon, boron, phosphorus, and arsenic. However; in terms of achieving higher gettering capability, the cluster ions preferably contain carbon as a constituent element. Carbon atoms at a lattice site have a smaller covalent radius than silicon single crystals, so that a compression site is produced in the silicon crystal lattice, which results in high gettering capability for attracting impurities in the lattice.

Further, the cluster ions more preferably contain at least two kinds of elements including carbon as constituent elements. Since the kinds of metals to be efficiently gettered depend on the kinds of the precipitated elements, solid solutions of two or more kinds of elements can cover a wider variety of metal contaminations. For example, carbon can efficiently getter nickel, whereas boron can efficiently getter copper and iron.

The compounds to be ionized are not limited in particular. Ethane, methane, carbon dioxide (CO₂), and the like can be used as ionizable carbon source compounds, whereas diborane, decaborane (B₁₀H₁₄), and the like can be used as ionizable boron source compounds. For example, when a mixed gas of benzyl and decaborane is used as a material gas, a hydrogen compound cluster in which carbon, boron, and hydrogen are aggregated can be produced. Alternatively, when cyclohexane (C₆H₁₂) is used as a material, cluster ions formed from carbon and hydrogen can be produced. In particular, CₙHₘ (3≤n≤16, 3≤m≤10)) clusters produced from pyrene (C₁₆H₁₀, dibenzyl (C₁₄H₁₄), or the like is preferably used. This is because cluster ion beams having a small size can be easily formed.

Further, the acceleration voltage and the cluster size of the cluster ions are controlled, thereby controlling the peak position of the concentration profile of the constituent elements in the depth direction of the modifying layer 18. “Cluster size” herein means the number of atoms or molecules constituting one cluster.

In the first step of this embodiment, in terms of achieving high gettering capability, the irradiation with the cluster ions 16 is performed such that the peak of the concentration profile of the constituent elements in the depth direction of the modifying layer 18 lies at a depth within 150 nm from the surface of the semiconductor wafer 10. Note that in this specification, in the case where the constituent elements include at least two kinds of elements, “the concentration profile of the constituent elements in the depth direction” means the profiles with respect to the respective single elements but not with respect to the total thereof.

For a condition required to set the peak positions to the depth level, when CₙHₘ (3≤n≤16, 3≤m≤10) is used as the cluster ions 16, the acceleration voltage per one carbon atom is set to be higher than 0 keV/atom and 50 keV/atom or less, and preferably 40 keV/atom or less. The cluster size is 2 to 100, preferably 60 or less, more preferably 50 or less.

In addition, for adjusting the acceleration voltage, two methods of (1) electrostatic field acceleration and (2) oscillating field acceleration are commonly used. Examples of the former method include a method in which a plurality of electrodes are arranged at regular intervals, and the same voltage is applied therebetween, thereby forming constant acceleration fields in the direction of the axes. Examples of the latter method include a linear acceleration (linac) method in which ions are transferred in a straight line and accelerated with high-frequency waves. The cluster size can be adjusted by controlling the pressure of gas ejected from a nozzle, the pressure of a vacuum vessel, the voltage applied to the filament in the ionization, and the like. The cluster size is determined by finding the cluster number distribution by mass spectrometry using oscillating quadrupole field or by time-of-flight mass spectrometry, and finding the mean value of the cluster numbers.

The dose of the cluster ions can be adjusted by controlling the ion irradiation time. In this embodiment, in order to achieve the gettering function, the dose of the cluster ions of carbon is preferably 1×10¹³ atoms/cm² to 1×10¹⁶ atoms/cm². In a case of a carbon dose of less than 1×10¹³ atoms/cm², sufficient gettering capability would not be achieved, whereas a dose exceeding 1×10¹⁶ atoms/cm² would cause great damage to the epitaxial surface. In particular, the dose of the cluster ions of carbon is preferably 2.0×10¹⁴ atoms/cm² or more. In this case, the crystal of the semiconductor wafer is damaged to a great extent, so that the crystallinity recovery due to the recovery heat treatment is more beneficial.

Another characteristic step of the present invention is the second of performing heat treatment for crystallinity recovery (recovery heat treatment) on the semiconductor wafer 10 such that the haze level of the semiconductor wafer surface portion 10A is 0.20 ppm or less (FIG. 1(C) and FIG. 2(D)). When the haze level of the semiconductor wafer surface portion 10A is 0.20 ppm or less and the epitaxial layer 20 is formed in the subsequent third step, the haze level of the epitaxial layer surface portion of the semiconductor epitaxial wafer can be 0.30 ppm or less.

Here, the haze level is an indicator of the surface roughness of the semiconductor wafer. When an epitaxial layer is formed on the semiconductor wafer, dulling referred to as haze is easily caused on the surface of the epitaxial layer, so that it is difficult to count light point defects (LPDs) using a particle counter and the quality of the semiconductor epitaxial wafer would not be secured. Correspondingly, the indicator is used. The haze level is obtained by irradiating the wafer surface with light (basically, laser light) and measuring the light scattered from the surface, as a ratio of the total scattered light with respect to the incident light. This measurement can be carried out by a given technique. For example, the wafer surface is observed using SP-1, a surface defect inspection apparatus produced by KLA-Tencor Corporation, in DWN mode (Darkfield Wide Normal mode: dark-field wide channel with normal incident mode), and the mean value of the obtained haze value can be evaluated as the haze level. In general, higher the surface roughness is, higher the haze level is.

In one embodiment, recovery heat treatment for obtaining a haze level of the semiconductor wafer surface 10A of 0.20 ppm or less can be performed also as hydrogen baking performed prior to epitaxial growth in an epitaxial apparatus for forming the epitaxial semiconductor layer 20, thus recovering the crystallinity of the silicon wafer 10. Here, for typical conditions for hydrogen baking, the epitaxial growth apparatus has a hydrogen atmosphere inside; and the silicon wafer 10 is placed in the furnace at a furnace temperature of 600° C. or more and 900° C. or less and heated to a temperature range of 1100° C. or more to 1200° C. or less at a heating rate of 1° C./s or higher to 15° C./s or lower, and the temperature is maintained for 30 s or more and 1 min or less. In this embodiment, in terms of sufficiently recovering the crystallinity, more intense heat treatment than the typical hydrogen baking is positively performed. In the conditions of recovery heat treatment covering hydrogen baking, the holding temperature can be 1100° C. to 1200° C. and the holding time can be 1 minute or more, and the holding time is preferably 2 minutes or more. The upper limit of the heat treatment time is not limited in particular; for example, it can be 10 minutes. Even if the heat treatment is performed for more than 10 minutes, the effect of recovering the crystallinity degraded by the cluster ion irradiation is saturated, and a longer heat treatment time leads to reduced productivity. Note that in the case where recovery heat treatment is performed also as the hydrogen baking performed prior to the epitaxial growth, when recovery heat treatment modelled on hydrogen baking is performed under the same conditions as hydrogen baking, the haze level of the surface portion 10A of the semiconductor wafer after the recovery heat treatment and before the formation of the epitaxial layer can be measured.

Further, in another embodiment of the recovery heat treatment, in the second step, RTA (Rapid Thermal Annealing), RTO (rapid thermal oxidation) or heat treatment using a rapid heating apparatus separate from the epitaxial apparatus, such as a batch heat treatment apparatus (vertical heat treatment apparatus or horizontal heat treatment apparatus), can be performed. Recovery heat treatment in that case can be performed at a recovery heat treatment condition of 900° C. to 1200° C. and 10 s to 1 h. Here, the baking temperature is 900° C. or more and 1200° C. or less because when it is less than 900° C., the crystallinity recovery effect can hardly be achieved, whereas when it is more than 1200° C., slips would be formed due to the heat treatment at a high temperature and the heat load on the apparatus would be increased. Further, the heat treatment time is 10 s or more and 1 h or less because when it is less than 10 s, the recovery effect can hardly be achieved, whereas when it is more than 1 h, the productivity would drop and the heat load on the apparatus would be increased. In that case, after performing the above recovery heat treatment, the semiconductor wafer 10 is transferred to an epitaxial growth apparatus, and the subsequent third step is performed. Note that when the dose of the cluster ions of carbon is 1.0×10¹⁵ atoms/cm² or more, the time required for recovery heat treatment increases; thus, the recovery heat treatment is preferably performed before the transfer to the epitaxial growth apparatus.

In the third step of this embodiment, the second epitaxial layer 20 formed on the modifying layer 18 may be an epitaxial silicon layer, and it can be formed under typical conditions. For example, a source gas such as dichlorosilane or trichlorosilane can be introduced into a chamber using hydrogen as a carrier gas, so that the source material can be epitaxially grown on the semiconductor wafer 10 by CVD at a temperature in the range of approximately 1000° C. to 1200° C., although the growth temperature depends also on the source gas to be used. The epitaxial layer 20 preferably has a thickness in the range of 1 μm to 15 μm. When the thickness is less than 1 μm, the resistivity of the second epitaxial layer 20 would change due to out-diffusion of dopants from the semiconductor wafer 10, whereas a thickness exceeding 15 μm would affect the spectral sensitivity characteristics of the solid-state image sensing device. The second epitaxial layer 20 is used as a device layer for producing a back-illuminated solid-state image sensing device.

The second embodiment shown in FIG. 2 also has a feature in that not the bulk semiconductor wafer 12 but the first epitaxial layer 14 is irradiated with cluster ions. The bulk semiconductor wafer has an oxygen concentration two orders of magnitude higher than that of the epitaxial layer. Accordingly, a larger amount of oxygen is diffused in the modifying layer formed in the bulk semiconductor wafer than in the modifying layer formed in the epitaxial layer, and the former modifying layer traps a large amount of oxygen. The trapped oxygen is released from the gettering site in a device fabrication process and diffused into an active region of the device to form point defects. This affects electrical characteristics of the device. Therefore, one important design condition in the device fabrication process is to irradiate an epitaxial layer having low solute oxygen concentration with cluster ions and to form a gettering layer in the epitaxial layer in which the effect of oxygen diffusion is almost negligible.

### (Semiconductor Epitaxial Wafer)

Next, the semiconductor epitaxial wafers 100 and 200 produced according to the above production methods will be described. A semiconductor epitaxial wafer 100 according to the first embodiment and a semiconductor epitaxial wafer 200 according to the second embodiment each has a semiconductor wafer 10; a modifying layer 18 formed from a certain element contained as a solid solution in the semiconductor wafer 10, formed in a surface portion of the semiconductor wafer 10; and an epitaxial layer 20 on this modifying layer 18, as shown in FIG. 1(D) and FIG. 2(E). Features of both of them are the concentration profile of the certain element in the depth direction of the modifying layer 18 has a half width W of 100 nm or less, and the haze level of the surface portion of the epitaxial layer 20 is 0.30 ppm or less.

Correspondingly, according to the production method of the present invention, the elements constituting cluster ions can be precipitated at a high concentration in a localized region as compared with monomer-ion implantation, which results in the half width of 100 nm or less. The lower limit thereof can be set to 10 nm. Note that the “concentration profile in the depth direction” herein means the concentration distribution in the depth direction, which is measured by secondary ion mass spectrometry (SIMS). Further, “the half width of the concentration profile of a certain element” is a half width of the concentration profile of the certain element measured by SIMS, with the epitaxial layer being thinned to 1 μm considering the measurement accuracy if the thickness of the epitaxial layer exceeds 1 nm.

Further, according to the production method of the present invention, the epitaxial layer 20 is formed after performing recovery heat treatment after cluster ion irradiation such that the haze level of the surface portion 10A of the semiconductor wafer 10 is 0.20 ppm or less, which allows the haze level to be 0.30 ppm or less. Note that the measurement of the haze level of the semiconductor epitaxial wafer surface portion can be performed in the like manner as the above-described haze level measurement of semiconductor wafer.

The certain element is not limited in particular as long as it is an element other than the main material of a semiconductor wafer (silicon when the semiconductor wafer is a silicon wafer). However, carbon or at least two kinds of elements including carbon are preferable as described above.

In terms of achieving higher gettering capability, for both of the semiconductor epitaxial wafers 100 and 200, the peak of the concentration profile in the modifying layer 18 lies at a depth within 150 nm from the surface of the semiconductor wafer 10. Further, the peak concentration of the concentration profile is preferably 1×10¹⁵ atoms/cm³ or more, more preferably in the range of 1×10¹⁷ atoms/cm³ to 1×10²² atoms/cm³, sill more preferably in the range of 1×10¹⁹ atoms/cm³ to 1×10²¹ atoms/cm³.

For both the semiconductor epitaxial wafers 100 and 200, the haze level of the surface portion of the epitaxial layer 20 is preferably 0.30 ppm or less, more preferably 0.26 ppm or less, and the lower limit can be set to 0.05 ppm.

The thickness of the modifying layer 18 in the depth direction can be approximately in the range of 30 nm to 400 nm.

According to the semiconductor epitaxial wafers 100 and 200 of this embodiment, higher gettering capability can be achieved than conventional, which makes it possible to further suppress metal contamination, and allows the haze level of the surface portion of the epitaxial layer to be 0.30 ppm or less.

### (Method of Producing Solid-State Image Sensing Device)

In a method of producing a solid-state image sensing device according to an embodiment of the present invention, a solid-state image sensing device can be formed on an epitaxial wafer produced according to the above producing methods or on the above epitaxial wafer, specifically, on the epitaxial layer 20 placed on the surface of the semiconductor epitaxial wafers 100 and 200. For solid-state image sensing devices obtained by this producing method, the effects of metal contamination caused during the steps in the production process can be reduced than conventional and white spot defects can be sufficiently suppressed than conventional.

Typical embodiments of the present invention have been described above; however, the present invention is not limited on those embodiments. For example, two layers of epitaxial layers may be formed on the semiconductor wafer 10.

### EXAMPLES

### Reference Experimental Examples

First, in order to clarify the difference between cluster ion irradiation and monomer ion implantation, experiments were carried out as follows.

### Reference Example 1

An n-type silicon wafer (diameter: 300 mm, thickness: 725 μm, dopant: phosphorus, dopant concentration: 4×10¹⁴ atoms/cm³) obtained from a CZ single crystal was prepared. Next, C₅H₅ clusters were generated from dibenzyl (C₁₄H₁₄) using a cluster ion generator (CLARIS produced by Nissin Lion Equipment Co., Ltd.) and a silicon wafer was irradiated with the clusters under the irradiation conditions of dose: 1.2×10¹⁴ Clusters/cm² (carbon dose: 6.0×10¹⁴ atoms/cm²), and acceleration voltage per one carbon atom: 14.8 keV/atom.

### Reference Example 2

The same silicon wafer as Reference Example 1 was implanted with monomer ions of carbon generated using CO₂ as a material gas, instead of being subjected to cluster ion irradiation, under the same irradiation conditions as Reference Example 1 except that the dose was 1.2×10¹⁴ atoms/cm² and the acceleration voltage was 300 keV/atom.

### (SIMS Results)

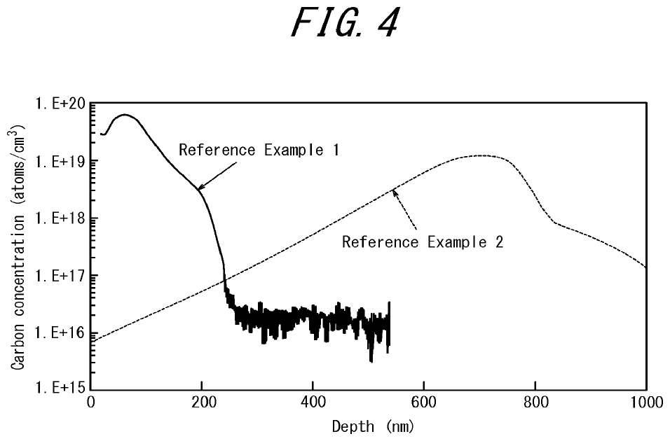

The samples prepared in Reference Examples 1 and 2 were subjected to SIMS analysis to obtain the concentration profile shown in FIG. 4. Note that the horizontal axis corresponds to the depth from the surface of the silicon wafer. As is clear from FIG. 4, in Reference Example 1, in which cluster ion irradiation was performed, the carbon concentration profile is sharp; on the other hand, in Reference Example 2, in which monomer ion implantation was performed, the carbon concentration profile is broad. Further, as compared with Reference Example 2, the peak concentration of the concentration profile of carbon is higher and the peak position is closer to the surface of the silicon wafer in Reference Examples 1. Therefore, the concentration profile of carbon after forming the epitaxial layer is presumed to have the same tendency.

### Example 1

An n-type silicon wafer (diameter: 300 nm, thickness: 725 μm, dopant: phosphorus, dopant concentration: 4×10¹⁴ atoms/cm³) obtained from a CZ single crystal was prepared. Next, C₅H₅ clusters were generated from dibenzyl (C₁₄H₁₄) using a cluster ion generator (CLAMS produced by Nissin Ion Equipment Co., Ltd.) and a silicon wafer was irradiated with the clusters under the irradiation conditions of dose: 1.2×10¹⁴ Clusters/cm² (carbon dose: 6.0×10¹⁴ atoms/cm²), and acceleration voltage per one carbon atom: 14.8 keV/atom. Subsequently, the silicon wafer was transferred to an epitaxial growth apparatus (produced by Applied Materials, Inc.) and subjected to heat treatment at 1130° C. for 2 min in the apparatus, which involves both recovery heat treatment for recovering the crystallinity degraded by the cluster ion irradiation and hydrogen baking. After that, an epitaxial silicon layer (thickness: 7 μm, dopant: phosphorus, dopant concentration: 1×10¹⁵ atoms/cm³) was then epitaxially grown on the silicon wafer by CVD at 1000° C. to 1150° C. using hydrogen as a carrier gas and trichlorosilane as a source gas, thereby preparing an epitaxial silicon wafer of the present invention.

### Example 2

An epitaxial silicon wafer according to the present invention was fabrication under the same conditions as Example 1 except for the following conditions. A silicon wafer was subjected to recovery heat treatment under the conditions of 900° C. for 10 s using an RTA apparatus (produced by Mattson Thermal Products GmbH) before being transferred to an epitaxial growth apparatus instead of the recovery heat treatment covering hydrogen baking, in the epitaxial apparatus. After that, the silicon wafer was transferred to the epitaxial growth apparatus and subjected to hydrogen baking under the conditions of a temperature of 1130° C. for 30 s in the apparatus, thereby growing an epitaxial layer.

### Example 3

An epitaxial silicon wafer according to the present invention was prepared in the same manner as Example 1 except that the cluster ion irradiation conditions are changed to the conditions shown in Table 1.

### Example 4

An epitaxial silicon wafer according to the present invention was prepared in the same manner as Example 2 except that the cluster ion irradiation conditions were changed to the conditions shown in Table 1.

### Comparative Examples 1 and 2

Epitaxial silicon wafers according to Comparative Examples 1 and 2 were prepared in the same manner as Example 2 except that the cluster ion irradiation conditions were changed to the conditions shown in Table 1 and the recovery heat treatment was not performed.

### Comparative Examples 3 and 4

Epitaxial silicon wafers according to Comparative Examples 3 and 4 were prepared in the same manner as Comparative Example 1 except that monomer ions of carbon was implanted under the conditions shown in Table 1 instead of being irradiated with cluster ions, and recovery heat treatment was performed under the conditions shown in Table 1.

### (Evaluation Method and Evaluation Result)

The samples prepared in Examples and Comparative Examples above were evaluated. The evaluation methods are shown below.

### (1) SIMS Analysis

The epitaxial silicon wafers of Example 1 and Comparative Example 4 were each analyzed as typical examples by SIMS to obtain the concentration profile of carbon shown in FIGS. 5(A) and 5(B). Note that the horizontal axis corresponds to the depth from the surface of the epitaxial layer. Further, each sample prepared in Examples 1 to 4 and Comparative Examples 1 to 4 was subjected to SIMS after thinning the epitaxial layer to 1 μm. Thus obtained half width, peak concentration, and peak position (peak depth from the surface with the epitaxial layer having been removed) of the concentration profile of carbon are shown in Table 1.

### (2) Gettering Capability Evaluation

The surface of the epitaxial silicon wafer in each of the samples prepared in Example 1 and Comparative Example 4 was contaminated on purpose by the spin coat contamination process using a Ni contaminating agent (1.0×10¹²/cm²) and was then subjected to heat treatment at 900° C. for 30 minutes. After that, SIMS analysis was carried out. The Ni concentration profile of Example 1 and Comparative Example 4 is shown with the carbon concentration profile thereof (FIGS. 5(A) and 5(B)). The results of the gettering capability evaluation of the other Examples and Comparative Examples are shown in Table 1. The peak concentration of the Ni concentration profile was classified into the following categories to be used as criteria.

++: 1.0×10¹⁷ atoms/cm³ or more
+: 5.0×10¹⁶ atoms/cm³ or more and less than 1.0×10¹⁷ atoms/cm³
−: less than 5.0×10¹⁰ atoms % cm³

### (3) Evaluation of Epitaxial Defects

Epitaxial defects observed in the epitaxial layer surface of each sample prepared in Examples and Comparative Examples were evaluated. The surface of each epitaxial layer was observed Using SP-2, a surface defect inspection apparatus produced by KLA-Tencor Corporation, in DWO mode (Dark Field Wide Oblique mode: Dark field Wide channel with Oblique incident mode), and the defect parts detected were observed at a fixed point using an atomic force microscope (AFM) and evaluated. The number of stacking faults (SFs) originated from crystal originated particles (COPS) observed in the epitaxial layer surface was counted, and evaluation was performed assuming the stacking faults as epitaxial defects. The evaluation results of the epitaxial defects are shown in Table 1. The evaluation criteria are as follows.

++: 2/wafer or less
+: more than 2/wafer and 10/wafer or less
−: more than 10/wafer and 50/wafer or less
−−: more than 50/wafer

### (4) Evaluation of Haze Level

For each sample prepared in Examples and Comparative Examples, the silicon wafer surface before the formation of the epitaxial layer and the epitaxial layer surface after the formation of the epitaxial layer were each observed using SP-1, a surface defect inspection apparatus produced by KLA-Tencor Corporation, in DWN mode, and the mean value of the haze value obtained was evaluated as the haze level. The results of the evaluation of the haze level are shown in Table 1. Note that for the haze level of the silicon wafer surface portion after the cluster ion irradiation and before the formation of the epitaxial layer in Examples 1 and 3, the haze level was measured after performing recovery heat treatment modelled on hydrogen baking.

TABLE 1

| | Cluster irradiation/Monomer implantation condition | | | | Recovery heat treatment | | |
|---|---|---|---|---|---|---|---|
| | | Irradiation/ | Acceleration | Dose* | condition | | |
| | | implantation | voltage | (Clusters/cm²) | Temp | | Apparatus |
| | Type | ion | (keV/atom) | (atoms/cm²) | (° C.) | Time | type |
| Example 1 | Cluster ion | C₅H₅ | 14.8 | 1.2 × 10¹⁴ | 1130 | 2 min | Epitaxial |
| | | | | | | | apparatus |
| Example 2 | Cluster ion | C₅H₅ | 14.8 | 1.2 × 10¹⁴ | 900 | 10 s | RTA |
| Comparative | Cluster ion | C₅H₅ | 14.8 | 1.2 × 10¹⁴ | — | — | — |
| Example 1 | | | | | | | |
| Example 3 | Cluster ion | C₃H₅ | 14.8 | 3.0 × 10¹⁴ | 1130 | 2 min | Epitaxial |
| | | | | | | | apparatus |
| Example 4 | Cluster ion | C₃H₅ | 14.8 | 3.0 × 10¹⁴ | 900 | 10 s | RTA |
| Comparative | Cluster ion | C₃H₅ | 14.8 | 3.0 × 10¹⁴ | — | — | — |
| Example 2 | | | | | | | |
| Comparative | Monomer | C | 300 | 1.2 × 10¹⁴ | — | — | — |
| Example 3 | ion | | | | | | |
| Comparative | Monomer | C | 300 | 1.2 × 10¹⁴ | 900 | 10 s | RTA |
| Example 4 | ion | | | | | | |

| | Evaluation | | | | | | |
|---|---|---|---|---|---|---|---|
| | before | | | | | | |
| | formation | | | | | | |
| | of | Evaluation of epitaxial silicon wafer | | | | | |
| | epitaxial | | Peak position | Peak value of | | | |
| | layer | Half | of carbon | carbon | Haze | | |
| | Haze level | width | concentration | concentration | level | Gettering | Epitaxial |
| | (ppm) | (nm) | (nm) | (atoms/cm³) | (ppm) | capability | defect |
| Example 1 | 0.155 | 91 | 50 | 3.00 × 10¹⁹ | 0.233 | ++ | ++ |
| Example 2 | 0.150 | 93 | 50 | 3.02 × 10¹⁹ | 0.215 | ++ | ++ |
| Comparative | 0.322 | 89 | 50 | 3.00 × 10¹⁹ | 0.350 | ++ | − |
| Example 1 | | | | | | | |
| Example 3 | 0.193 | 96 | 80 | 4.00 × 10¹⁹ | 0.256 | ++ | ++ |
| Example 4 | 0.190 | 96 | 80 | 3.98 × 10¹⁹ | 0.260 | ++ | ++ |
| Comparative | 0.507 | 95 | 80 | 4.01 × 10¹⁹ | 5.970 | ++ | − |
| Example 2 | | | | | | | |
| Comparative | 0.157 | 270 | 700 | 1.00 × 10¹⁹ | 0.275 | − | −− |
| Example 3 | | | | | | | |
| Comparative | 0.140 | 270 | 700 | 1.03 × 10¹⁹ | 0.270 | − | + |
| Example 4 | | | | | | | |

*The unit Clusters/cm² is used in the case of cluster ion irradiation, whereas the unit atoms/cm² is used in the case of monomer ion implantation.

### (Discussion on Evaluation Results)

FIGS. 5(A) and 5(B) show that a modifying layer formed from carbon contained as a solid solution localized at high concentration as compared with Comparative Example 4 is formed by the cluster ion irradiation in Example 1. Further, comparing Example 1 with Comparative Example 4, the Ni concentration profiles indicate that the modifying layer formed by the cluster ion irradiation in Example 1 trapped a large amount of Ni, thus achieving high gettering capability. As Table 1 shows, in each of Examples 1 to 4 and Comparative Examples 1 and 2, in which the cluster ion irradiation was performed, the half width is 100 nm or less, which resulted in sufficient gettering capability. On the other hand, in each of Comparative Examples 3 and 4 in which monomer ion implantation was performed, the half width exceeds 100 nm, which resulted in in sufficient gettering capability. Thus, as compared with Comparative Examples 3 and 4 in which monomer ion implantation was performed, higher gettering was obtained in Examples 1 to 4 and Comparative Examples 1 and 2 in which cluster ion irradiation was performed, since the half width of the carbon concentration profile was smaller.

Reference is now made to Table 1 concerning the haze level. Comparing Examples 1 to 4 in which recovery heat treatment was performed with Comparative Examples 1 and 2 in which recovery heat treatment was not performed, in either of which cluster ion irradiation was performed, in Examples 1 to 4, the haze level of the epitaxial layer surface portion was 0.30 ppm or less due to the recovery heat treatment, whereas a haze level of 0.30 ppm or less was not achieved in Comparative Examples 1 and 2 without recovery heat treatment. Thus, it was found that in order to obtain an epitaxial silicon wafer having a haze level of 0.30 ppm or less in the case of performing cluster ion irradiation, the recovery heat treatment is required to be performed such that the haze level of the silicon wafer surface portion is 0.20 ppm or less before the formation of the epitaxial layer. Further, comparing Comparative Example 3 with Comparative Example 4, it was found that the haze level was recovered by recovery heat treatment even in the case of monomer ion implantation; however, the recovery effect is small. This may be attributed to that in the case of cluster ion irradiation, the flatness of the silicon wafer surface is deteriorated; whereas the crystallinity of the surface portion of silicon wafer was significantly degraded due to high energy in the case of monomer ion implantation.

Note that Table 1 also indicates the correlation between the haze level and the epitaxial defects. Specifically, as the haze level is low, better results are obtained with respect to the epitaxial defects.

The above results indicate that cluster ion irradiation is required in order to achieve higher gettering capability as shown in Examples. Further, it was found that performing recovery heat treatment after cluster ion irradiation reduces the haze level of the epitaxial layer surface portion to a sufficiently low level as 0.30 ppm or less.

### INDUSTRIAL APPLICABILITY

According to the present invention, a semiconductor epitaxial wafer can be obtained, which can suppress metal contamination and the haze level of the surface portion of an epitaxial layer of which is reduced by achieving higher gettering capability; and a high quality solid-state image sensing device can be formed from the semiconductor epitaxial wafer.

### REFERENCE SIGNS LIST

10: Semiconductor wafer
10A: Surface portion of semiconductor wafer
12: Bulk semiconductor wafer
14: First epitaxial layer
16: Cluster ions
18: Modifying layer
20: (Second) epitaxial layer
100: Semiconductor epitaxial wafer
200: Semiconductor epitaxial wafer

1. A method of producing a semiconductor epitaxial wafer, comprising:
a first step of irradiating a semiconductor wafer with cluster ions thereby forming a modifying layer formed from a constituent element of the cluster ions contained as a solid solution, in a surface portion of the semiconductor wafer;
a second step of performing heat treatment for crystallinity recovery on the semiconductor wafer after the first step such that the haze level of the surface portion of the semiconductor wafer is 0.20 ppm or less; and
a third step of forming an epitaxial layer on the modifying layer of the semiconductor wafer after the second step.

2. The method of producing a semiconductor epitaxial wafer, according to claim 1, wherein the semiconductor wafer is a silicon wafer.

3. The method of producing a semiconductor epitaxial wafer, according to claim 1, wherein the semiconductor wafer is an epitaxial silicon wafer in which a silicon epitaxial layer is formed on a surface of a silicon wafer, and the modifying layer is formed in a surface portion of the silicon epitaxial layer in the first step.

4. The method of producing a semiconductor epitaxial wafer, according to any one of claims 1 to 3, wherein the cluster ions contain carbon as a constituent element.

5. The method of producing a semiconductor epitaxial wafer, according to claim 4, wherein the cluster ions contain at least two kinds of elements including carbon as constituent elements.

6. The method of producing a semiconductor epitaxial wafer, according to claim 4 or 5, wherein the dose of the cluster ions of carbon is 2.0×10¹⁴ atoms/cm² or more.

7. A semiconductor epitaxial wafer, comprising:
a semiconductor wafer; a modifying layer formed from a certain element contained as a solid solution in the semiconductor wafer, the modifying layer being formed in a surface portion of the semiconductor wafer; and an epitaxial layer on the modifying layer,
wherein the half width of the concentration profile of the certain element in the depth direction of the modifying layer is 100 nm or less, and the haze level of the surface portion of the epitaxial layer is 0.30 ppm or less.

8. The semiconductor epitaxial wafer according to claim 7, wherein the semiconductor wafer is a silicon wafer.

9. The semiconductor epitaxial wafer according to claim 7, wherein the semiconductor wafer is an epitaxial silicon wafer in which an epitaxial silicon layer is formed on a surface of a silicon wafer, and the modifying layer is placed in the surface portion of the epitaxial silicon layer.

10. The semiconductor epitaxial wafer according to any one of claims 7 to 9, wherein the peak of the concentration profile in the modifying layer lies at a depth within 150 nm from the surface of the semiconductor wafer.

11. The semiconductor epitaxial wafer according to any one of claims 7 to 10, wherein the peak concentration of the concentration profile of the modifying layer is 1×10¹⁵ atoms/cm³ or more.

12. The semiconductor epitaxial wafer according to any one of claims 7 to 11, wherein the certain element includes carbon.

13. The semiconductor epitaxial wafer according to claim 12, wherein the certain element includes at least two kinds of elements including carbon.

14. A method of producing a solid-state image sensing device, wherein a solid-state image sensing device is formed in an epitaxial layer placed on the surface portion of the epitaxial wafer fabricated by the production method according to any one of claims 1 to 6 or of the epitaxial wafer according to any one of claims 7 to 13.
